(19) United States
(12) Patent Application Publication
(10) Pub. No.: US 2002/0111021 A1
(43) Pub. Date: Aug. 15, 2002

(54) Ozone oxide as a mediating layer in nickel silicide formation

(75) Inventors: Eric N. Paton, Morgan Hill, CA (US); Terri J. Kitson, San Jose, CA (US); Jeffrey S. Glick, Cupertino, CA (US); John C. Foster, Mountain View, CA (US)

Correspondence Address: McDERMOTT, WILL & EMERY, 600 13th Street, N.W., Washington, DC, 20005-3096, US

(73) Assignee: ADVANCED MICRO DEVICES, INC.

(21) Appl. No.: 09/781,240

(22) Filed: Feb. 13, 2001

(51) Int. Cl. H01L 21/44; H01L 21/31; H01L 21/469; H01L 21/4763

(52) U.S. Cl. 438/682; 438/651; 438/655; 438/768

(57) ABSTRACT

Nickel salicide processing is implemented by forming a non-stoicheiometric mediating layer, such as ozonated SiOx, to control the reaction of Ni and Si during annealing to form a NiSi layer on the polysilicon gate electrodes and source/drain regions without conductive bridging between the metal silicide layer on the gate electrode and the metal silicide layers on associated source/drain regions. Embodiments of the present invention comprise forming silicon nitride sidewall spacers on the side surfaces of the gate electrode.

### FIELD OF THE INVENTION

The present invention relates to semiconductor device fabrication, particularly to self-aligned silicide (salicide) technology.

### BACKGROUND ART

As gate electrode lengths are scaled down, the source and drain junctions and polycrystalline silicon line width must also be scaled down. However, scaling down the source and drain junctions and polycrystalline line width increases parasitic resistance in the source and drain diffusion layers and the gate electrode, and also increases the sheet and contact resistance of the gate electrode and source/drain regions.

Salicide technology comprises forming metal silicide layers on the source/drain regions and/or on the gate electrode of a semiconductor device in a self-aligned manner. A conventional approach to reduce resistivity involves forming a multi-layered structure comprising a low resistance refractory metal silicide layer on a doped polycrystalline silicon, typically referred to as a polycide. Salicide technology reduces parasitic, sheet and contact resistance in the source and drain diffusion layers and the gate electrode that results from scaling down the source and drain junctions and polycrystalline silicon line width.

Silicides are typically formed by reacting a metal with silicon (Si) within a specified temperature range for a specific period of time. Silicide layers may be self-aligned by different techniques. For example, the metal can be selectively deposited on the gate electrode and on the source/drain regions, with subsequent annealing to react the metal with underlying Si of the source/drain regions and the gate electrode to form the metal silicide layers. Alternatively, sidewall spacers, e.g., silicon nitride or silicon dioxide, are formed on the side surfaces of the gate electrode, followed by a blanket deposition of metal and annealing to react the metal with Si in the gate electrode and the source/drain regions, while the sidewall spacers prevent reaction with Si from the side surfaces of the gate electrode.

During annealing, the wafer is heated to a reaction temperature and held at the reaction temperature for a period of time sufficient for the metal layer to react with underlying Si to form a metal silicide layer on the source/drain regions and the gate electrode. Multiple annealing steps may be employed.

Various metals react with Si to form a metal silicide, however, titanium (Ti) and cobalt (Co) are currently the most common metals used to create metal silicides when manufacturing semiconductor devices utilizing salicide technology. However, Ti and Co silicides have certain characteristics that negatively impact semiconductor device performance.

Titanium silicide imposes high sheet resistance for lines narrower than 0.35 micrometers. For example, as TiSi₂ is formed in narrower and narrower lines, the resistance increases. Another significant limitation is that TiSi₂ initially forms a high resistivity phase (C49), and transformation from C49 to a low resistivity phase (C54) is nucleation limited, e.g., a high temperature is required to affect the phase change.

Cobalt silicide, unlike TiSi₂, exhibits less line width dependence of sheet resistance. However, CoSi₂ consumes significant amounts of Si during formation, which increases the difficulty of forming shallow junctions. Large Si consumption is also a concern where the amount of Si present is limited, for example, with Si on insulator (SIO) substrates. Without enough Si to react with Co to form CoSi₂, a thin layer of CoSi₂ results. The thickness of the metal silicide layer is an important parameter because a thin metal silicide layer is more resistive than a thicker metal silicide layer of the same material. Therefore, thicker metal silicide layers increase semiconductor device speed, while thinner metal silicide layers reduce device speed.

Recently, attention has turned towards nickel (Ni) to form nickel silicide utilizing salicide technology. Nickel silicide avoids many limitations associated with TiSi₂ and CoSi₂. Unlike Ti where Si diffuses into the metal layer when forming a Ti silicide, Ni, like Co, diffuses into Si, which helps to limit bridging between the metal silicide layer on the gate electrode and a metal silicide layer on the associated source/drain regions. The formation of nickel silicide requires less Si than TiSi₂ and CoSi₂. Nickel silicide also exhibits almost no line width dependence on sheet resistance. Nickel silicide is normally annealed in a one step process, vis-à-vis a process requiring an anneal, an etch, and a second anneal, as occurs in TiSi₂ and CoSi₂ saliciding. In addition, nickel silicide exhibits lower film stress, i.e., causes less wafer distortion, than conventional Ti or Co silicides.

Although the use of Ni in salicide technology has certain advantages over using Ti or Co, there are problems associated with Ni. Metal silicide resistivity and, thus, semiconductor device performance, varies based on whether the silicide is metal-rich. Low resistivity is the preferred phase for metal silicides, including nickel silicide, as it improves device performance in the areas of switching speed and source to drain drive current. It is difficult to control nickel silicide transformation with conventional salicide technology in a manner that effects transformation to the desirable NiSi low resistivity phase from the undesirable Ni₂Si or Ni₃Si high resistivity phase without forming bridges between the nickel silicide layer on the gate electrode and nickel silicide layers on the associated source/drain regions.

With conventional salicide technology, the metal layer is deposited in direct contact with the Si in the gate electrode and source/drain regions. The wafer is then heated to a sufficient temperature to cause the metal to react with underlying Si, typically at about 450° C. or greater when Ni is used. The reservoir of Ni abutting the Si results in rapid nickel silicide transformation during annealing.

The transformation to a low resistivity nickel silicide is affected by the temperature at which annealing occurs. In order to convert Ni₂Si or Ni₃Si to NiSi, annealing typically must occur at 450° C. or greater. However, the higher annealing temperatures result in undesirable bridging, particularly when silicon nitride sidewall spacers are used. Sidewall spacers typically comprise silicon dioxide or silicon nitride, but silicon nitride sidewall spacers are often preferable because silicon nitride is highly conformal and the sidewall spacers can be added and removed as needed throughout out the manufacturing process. However, at typical annealing temperatures, conductive bridges form between the nickel silicide layer on the gate electrode and the nickel silicide layers on associated source/drain regions, particularly when Ni is used. Such bridging interferes with semiconductor device performance by creating electrical shorts between different regions of the semiconductor device.

There exists a need for salicide technology that enables the formation of a low resistive nickel silicide layer on the gate electrode and source/drain regions of a semiconductor device. There also exists a need for salicide technology that avoids bridging between the nickel silicide layer on the gate electrode and the nickel silicide layers on associated source/drain regions when using silicon nitride sidewall spacers.

### DISCLOSURE OF THE INVENTION

These and other needs are met by embodiments of the present invention, which provide a method of salicide processing in semiconductor device fabrication, the method comprising forming a non-stoicheiometric mediating layer, depositing a Ni layer over the mediating layer, and heating to react the Ni with underlying Si to form a nickel silicide layer on the polysilicon gate electrode and source/drain regions. Wet chemical etching is then conducted to remove unreacted Ni from the silicon nitride sidewall spacers. In an embodiment of the present invention, ozonated SiOx serves as the mediating layer.

An advantage of the present invention is the ability to control Ni diffusion into the Si of the gate electrode and source/drain regions with a non-stoicheiometric mediating layer between the gate electrode and source/drain regions and the deposited Ni. The presence of a mediating layer slows but does not completely inhibit Ni diffusion, thereby improving control over the nickel silicide transformation process.

The Ni diffusion rate is further controlled in embodiments of the present invention by reducing the temperature at which annealing is conducted, from the conventional level of approximately 450° C. or greater down to a temperature of approximately 150° C. to approximately 350° C. The present invention advantageously enables a reduction in the temperature required to form a NiSi layer on the polysilicon gate electrode and source/drain regions.

The reduced annealing temperature and the presence of a mediating layer improves semiconductor device performance by avoiding bridging between the nickel silicide layer on the gate electrode and the nickel silicide layers on associated source/drain regions when using silicon nitride sidewall spacers.

A further aspect of the present invention relates to a semiconductor device that includes a polysilicon gate electrode, source/drain regions, and silicon nitride sidewall spacers. A NiSi layer is present on the polysilicon gate electrode and source/drain regions, wherein the NiSi layer is created by forming an ozonated SiOx mediating layer, depositing a Ni layer over the mediating layer, heating to react the Ni with Si from the polysilicon gate electrode and source/drain regions to form a nickel silicide layer on the polysilicon gate electrode and source/drain regions and wet chemical etching to remove unreacted Ni from the silicon nitride sidewall spacers.

An advantage of the present invention is improved semiconductor performance resulting from the formation of a low resistivity nickel silicide layer on the gate electrode and associated source/drain regions and the avoidance of conductive bridges between the nickel silicide layer on the gate electrode and the nickel silicide layers on associated source/drain regions when using silicon nitride sidewall spacers.

Other advantages of the present invention will become readily apparent to those skilled in the art from the following detailed description. The embodiments shown and described provide illustration of the best mode contemplated for carrying out the invention. The invention is capable of modifications in various obvious respects, all without departing from the invention. Accordingly, the drawings are to be regarded as illustrative in nature, and not as restrictive.

### BRIEF DESCRIPTION OF THE DRAWINGS

Reference is made to the attached drawings, wherein elements having the same reference numeral designations represent like elements throughout.

FIGS. 1-3 schematically illustrate sequential phases in a conventional salicide technique employing silicon nitride sidewall spacers and conductive bridging between the metal silicide layer on the gate electrode and the metal silicide layers on associated source/drain regions.

FIGS. 4-6 schematically illustrate a method in accordance with an embodiment of the present invention using a mediating layer and avoiding conductive bridging between the nickel silicide layer on the gate electrode and the nickel silicide layers on the associated source/drain regions.

### DETAILED DESCRIPTION OF THE INVENTION

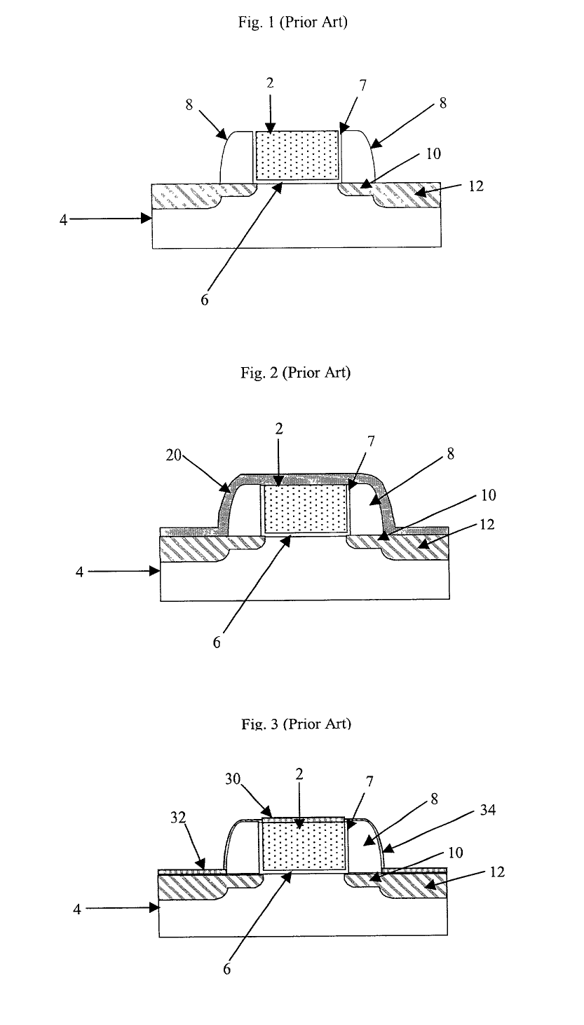

The present invention addresses and solves problems related to formation of a metal silicide layer on the gate electrode and source/drain regions of a semiconductor device. As device geometries shrink into the deep sub-micron regime, metal silicide bridging occurs along the surface of silicon nitride sidewall spacers between the metal silicide layer on the gate electrode and metal silicide layers on associated source/drain regions. For example, adverting to FIG. 1, in attempting to implement nickel silicide technology utilizing silicon nitride sidewall spacers, a gate electrode 2 is formed on silicon substrate 4 with a gate insulating layer 6 therebetween. A spacer liner oxide 7 is disposed as a buffer layer on the side surfaces of the gate electrode 2. A conformal layer of silicon nitride is then deposited followed by anisotropic etching to form silicon nitride sidewall spacers 8 on opposing side surfaces of gate electrode 2. After anisotropic etching, contamination such as etching residues are removed by wet cleaning. Shallow source/drain extensions 10 and source/drain regions 12 are formed in a conventional manner.

Adverting to FIG. 2, a Ni layer 20 is deposited over the wafer surface. The wafer is then subject to annealing to react Ni with the underlying Si.

As shown in FIG. 3, following annealing, a nickel silicide layer 30 is formed on the upper surface of gate electrode 2 and a layer of nickel silicide 32 on associated source/drain regions 12. However, when using conventional salicide technology, the reaction between the deposited Ni and Si causes the formation of high resistivity nickel silicides e.g., Ni₂Si or Ni₃Si, on the source/drain regions 12 and gate electrode 2, thereby impeding semiconductor device performance.

The annealing temperature conventionally employed for nickel silicidation, in part, affects the resistivity phase of the resulting nickel silicide layer. In conventional nickel silicidation processes, heating is conducted at a temperature of about 450° C. or greater. This temperature level is required to drive the reaction between the deposited Ni and underlying Si to form low resistivity nickel silicide, e.g., NiSi, versus high resistivity nickel silicides, e.g., Ni₂Si or Ni₃Si, on the upper surface of gate electrode 2 and on associated source/drain regions 12. However, it was found that a thin layer of nickel silicide 34, as at a thickness of about 30 Å to 60 Å, is undesirably formed along the exposed surfaces of silicon nitride sidewall spacers 8 causing bridging and, hence, shorting between nickel silicide layer 30 and nickel silicide layers 32.

After considerable experimentation and investigation, it was postulated that the problem of nickel silicide formation 34 along the silicon nitride sidewall spacers 8 stemmed from the direct contact between the deposited Ni and dangling Si bonds in the silicon nitride sidewall spacers 8. It was also postulated that the high temperatures at which heating, as by rapid thermal annealing or furnace annealing, typically occurs to form low resistivity nickel silcide, e.g., NiSi, enabled nickel to react with dangling Si bonds in the silicon nitride sidewall spacers 8, thus causing nickel silicide formation 34 along the silicon nitride sidewall spacers 8. The present invention addresses and solves such problems by reducing the nickel silicidation temperature and avoiding direct contact between the deposited Ni and the gate electrode 2, the associated source/drain regions 12 and the silicon nitride sidewall spacers 8.

In accordance with embodiments of the present invention, a non-stoicheiometric mediating layer is formed over the gate electrode, source/drain regions and silicon nitride sidewall spacers prior to Ni deposition and annealing. It was found that the mediating layer advantageously slows but does not prevent deposited Ni from diffusing and reacting with Si in the gate electrode and source/drain regions, thereby facilitating control over resistivity phase changes during nickel silicide formation. Nickel silicide transformation is further controlled by reducing the temperature at which annealing occurs, thereby allowing the nickel silicide transformation process to be stopped at the NiSi phase. The mediating layer and reduced annealing temperature beneficially prevents reaction between the deposited Ni and free Si from the silicon nitride sidewall spacers, thereby avoiding metal silicide bridging, such as that denoted by reference numeral 34 in FIG. 3.

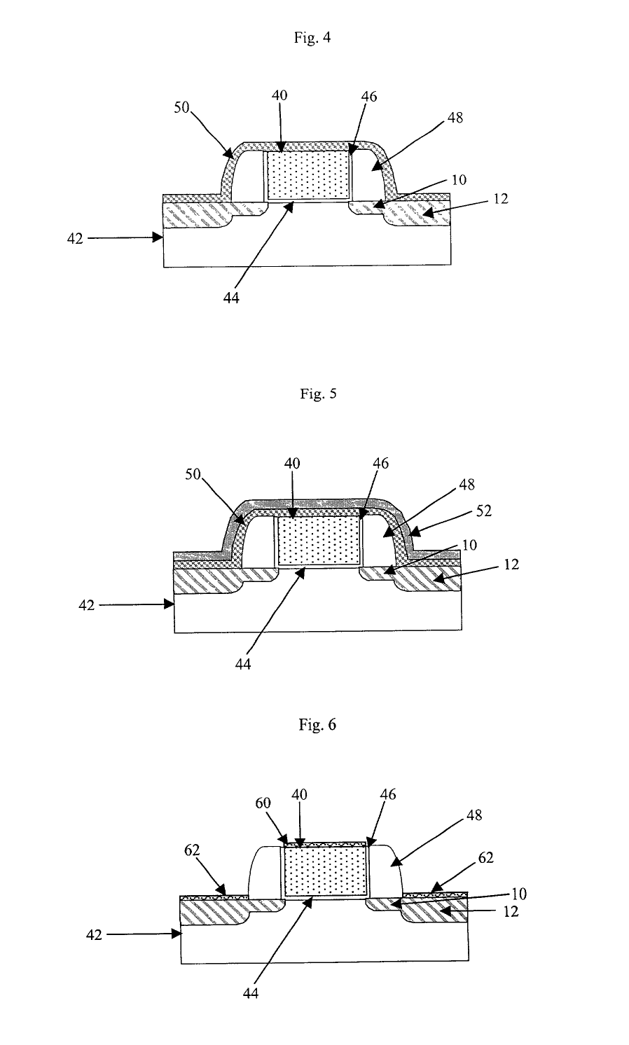

An embodiment of the present invention is illustrated in FIGS. 4 through 6, wherein similar reference numerals denote similar features. Adverting to FIG. 4, a gate electrode 40, e.g., doped polycrystalline silicon, is formed on substrate 42, which can be n-type or p-type doped silicon, with a gate insulating layer 44 therebetween. Gate insulating layer 44 is typically silicon dioxide formed by thermal oxidation or chemical vapor deposition (CVD). A spacer liner oxide 46 is disposed on the opposing side surfaces of gate electrode 40 as a buffer between silicon nitride sidewall spacers 48 and the side surfaces of the gate electrode 40. Shallow source/drain extensions 10 and source/drain regions 12 are formed in a conventional manner.

Subsequent to forming silicon liner oxide 46, silicon nitride sidewall spacers 48 are formed by depositing a conformal layer and anisotropic etching. Silicon nitride sidewall spacers 48 can be formed by plasma-enhanced chemical vapor deposition (PECVD). After anisotropic etching, contamination such as etching residues are removed by wet cleaning.

As depicted in FIG. 4, with the silicon nitride sidewall spacers 48 in place, a non-stoicheiometric mediating layer 50 is formed on polysilicon gate electrode 40, source/drain regions 12 and silicon nitride sidewall spacers 48. In an embodiment of the present invention, the non-stoicheiometric mediating layer 50 is an ozone oxide layer, e.g., an ozonated SiOx layer, formed by bubbling ozone into deionized water and immersing the wafer in the ozonated water, e.g., by dipping or spraying. The wafer can be immersed for approximately 10 minutes to approximately 20 minutes, e.g., for approximately 12 minutes, to form mediating layer 50 having a suitable thickness, e.g., approximately 6 Å to approximately 25 Å, such as approximately 6 Å to approximately 15 Å or, for example, approximately 11 Å. The mediating layer 50 in accordance with embodiments of the present invention beneficially slows but does not prevent deposited Ni from diffusing and reacting with Si from the gate electrode 40 and source/drain regions 12, thereby facilitating control over nickel silicide formation and avoiding conductive bridges on the sidewall spacers 48.

As depicted in FIG. 5, a Ni layer 52 is deposited, as by sputtering in a conventional deposition chamber or other conventional method, over the mediating layer 50.

Turning to FIG. 6, in order to achieve the desired nickel silicide layer, e.g., NiSi, the wafer is heated, e.g., as by rapid thermal annealing or furnace annealing, to react the deposited Ni with underlying Si to form a nickel silicide layer 60 on the gate electrode 40 and to form nickel silicide layers 62 on the source/drain regions 12. In an embodiment of the present invention, heating is conducted at a reduced temperature of approximately 150° C. to approximately 350° C., e.g., approximately 250° C. to approximately 350° C., to effect nickel silicidation vis-à-vis the conventional temperature of 450° C. During heating, e.g., rapid thermal annealing, a nickel silicide layer 60, e.g., NiSi, is formed on the gate electrode 40 and nickel silicide layers 62 are formed on the source/drain regions 12, as in approximately 15 seconds to approximately 120 seconds, e.g., approximately 30 seconds to approximately 60 seconds. In alternative embodiments of the present invention, a nickel silicide layer 60, e.g., NiSi, is formed on the gate electrode 40 and nickel silicide layers 62 are formed on the source/drain regions 12 using furnace annealing for approximately 30 minutes to approximately 45 minutes.

Embodiments of the present invention beneficially enable control over Ni diffusion into the Si of the gate electrode 40 and source/drain regions 12 so as to limit nickel silicide formation to the low resistivity phase, e.g., NiSi, from the high resistivity phase, Ni₂Si or Ni₃Si, thereby improving semiconductor performance. This is achieved by the use of a non-stoicheiometric mediating layer 50, for example ozone oxide, e.g. ozonated SiOx, mediating layer, that slows but does not prevent Ni diffusion. The Ni diffusion rate is further controlled in embodiments of the present invention by reducing the temperature at which annealing is conducted, down to a temperature of approximately 150° C. to approximately 350° C. The present invention advantageously allows annealing to occur at temperatures sufficient to form low resistivity NiSi layers 60 and 62 on the polysilicon gate electrode 40 and source/drain regions 12 respectively.

The reduced annealing temperatures and the presence of a mediating layer 50 between the silicon nitride sidewall spacers 48 and the Ni layer 52 associated with embodiments of the present invention further improve semiconductor device performance by avoiding conductive bridging between the nickel silicide layer 60 on the gate electrode 40 and the nickel silicide layers 62 on associated source/drain regions 12 when using silicon nitride sidewall spacers 48. This beneficially eliminates a cause of electrical shorts between different regions of the semiconductor device.

Another aspect of the present invention relates to a semiconductor device that includes a polysilicon gate electrode 40, source/drain regions 12, and silicon nitride sidewall spacers 48, wherein NiSi layers 60 and 62 are present on the gate electrode 40 and source/drain regions 12. The NiSi layers 60 and 62 are created by initially forming a mediating layer 50, for example an ozone oxide mediating layer, e.g., ozonated SiOx, depositing a Ni layer 52 over the mediating layer 50, heating to react the deposited Ni layer 52 with underlying Si in the polysilicon gate electrode 40 and source/drain regions 12 to form NiSi layers 60 and 62 on the polysilicon gate electrode 40 and source/drain regions 12 respectively, and wet chemical etching the unreacted Ni from the silicon nitride sidewall spacers 48.

The present invention enjoys industrial applicability in fabricating any of various types of semiconductor devices. The present invention has particular applicability in devices with high circuit speeds having design features in the deep sub-micron regime.

Only the preferred embodiment of the invention and but a few examples of its versatility are shown and described in the present disclosure. It is to be understood that the invention is capable of use in various other combinations and environments and is capable of changes or modifications within the scope of the inventive concept as expressed herein. Well-known processing structures have not been described in detail in order not to unnecessarily obscure the present invention.

What is claimed is:

1. A method of salicide processing in semiconductor device manufacture, the method comprising the steps of:
forming a silicon gate electrode, having an upper surface and side surfaces, overlying a silicon substrate with a gate dielectric layer therebetween and source/drain regions in the substrate and a dielectric sidewall spacer disposed on each side surface;
forming a non-stoicheiometric mediating layer on the gate electrode, source/drain regions and sidewall spacers;
depositing a Ni layer over the mediating layer;
heating to react the Ni with underlymg Si to form a nickel silicide layer on the gate electrode and a nickel silicide layer on the source/drain regions; and
wet chemical etching to remove unreacted Ni from the sidewall spacers.

2. The method of claim 1, wherein the non-stoicheiometric mediating layer is an ozone oxide layer.

3. The method of claim 2, wherein the non-stoicheiometric mediating layer is an ozonated SiOx layer.

4. The method of claim 2, wherein the sidewall spacers comprise silicon nitride.

5. The method of claim 4, wherein a silicon liner oxide is disposed between each sidewall spacer and the side surfaces.

6. The method of claim 2, comprising forming the mediating layer by:
bubbling ozone into deionized water to form ozonated water; and
immersing the substrate in the ozonated water.

7. The method of claim 6, comprising immersing the substrate in the ozonated water for approximately 10 minutes to approximately 20 minutes to form the mediating layer.

8. The method of claim 7, comprising immersing the substrate in the ozonated water for approximately 12 minutes to form the mediating layer.

9. The method of claim 7, comprising immersing the substrate in the ozonated water to form the mediating layer at a thickness of approximately 6 Å to approximately 25 Å.

10. The method of claim 9, comprising immersing the substrate in the ozonated water to form the mediating layer at a thickness of approximately 6 Å to approximately 15 Å.

11. The method of claim 10, comprising immersing the substrate in the ozonated water to form the mediating layer at a thickness of approximately 11 Å.

12. The method of claim 9, comprising heating to form the nickel silicide layer on the gate electrode and source/drain regions at a temperature of approximately 150° C. to approximately 350° C.

13. The method of claim 12, comprising heating to form the nickel silicide layer on the gate electrode and source/drain regions at a temperature of approximately 250° C. to approximately 350° C.

14. The method of claim 12, comprising heating by rapid thermal annealing to form the nickel silicide layer on the gate electrode and source/drain regions for approximately 15 seconds to approximately 120 seconds.

15. The method of claim 14, comprising heating by rapid thermal annealing to form the nickel silicide layer on the gate electrode and source/drain regions for approximately 30 seconds to approximately 60 seconds.

16. The method of claim 12, comprising heating by furnace annealing to form the nickel silicide layer on the gate electrode and source/drain regions for approximately 30 minutes to approximately 45 minutes.

17. The method of claim 1, wherein the nickel silicide layer formed on the polysilicon gate electrode and source/drain regions is NiSi.

18. A semiconductor device produced by the method of claim 1.
